(19) United States
(12) Patent Application Publication
(10) Pub. No.: US 2015/0263068 A1
(43) Pub. Date: Sep. 17, 2015

(54) VARIABLE RESISTANCE MEMORY AND THE METHOD OF CONTROLLING THE SAME

(71) Applicant: KABUSHIKI KAISHA TOSHIBA, Tokyo (JP)

(72) Inventor: Yuichi ITO, Yokohama (JP)

(73) Assignee: KABUSHIKI KAISHA TOSHIBA, Tokyo (JP)

(21) Appl. No.: 14/479,018

(22) Filed: Sep. 5, 2014

Related U.S. Application Data
(60) Provisional application No. 61/952,625, filed on Mar. 13, 2014.

(51) Int. Cl. H01L 27/22; H01L 43/08; G11C 11/16; H01L 43/02

(52) U.S. Cl. CPC H01L 27/228; H01L 43/02; H01L 43/08; G11C 11/1673; G11C 11/1675; G11C 11/1659; G11C 11/1657

(57) ABSTRACT

According to one embodiment, a variable resistance memory including a bit line extending in a first direction, a word line extending in a second direction, and a memory cell array including memory cells, each of the memory cells including a variable resistance element and a selective transistor, the element being configured to store two-bit data using a change in resistance, the element being connected to the bit line, a gate of the selective transistor being connected to the word line, wherein a first and a second write current are selectively applied to the element, to enable the data to be written, and a first and a second read current are selectively applied to the element, to enable the data to be read.

### CROSS-REFERENCE TO RELATED APPLICATIONS

This application claims the benefit of U.S. Provisional Application No. 61/952,625, filed Mar. 13, 2014, the entire contents of which are incorporated herein by reference.

### FIELD

Embodiments described herein relate generally to a variable resistance memory with a variable resistance element capable of storing data utilizing changes in its resistance.

### BACKGROUND

Variable resistance memories capable of storing data utilizing changes in the resistance of a storing element include a magnetic random access memory (MRAM), a resistive random access memory (ReRAM), a phase-change random access member (PCRAM), etc.

Among these variable resistance memories, an MRAM utilizing a spin injection write method is disclosed.

### BRIEF DESCRIPTION OF THE DRAWINGS

FIG. 1 is a block diagram showing the configuration of an MRAM according to a first embodiment;

FIG. 2 is a plan view showing a memory cell array according to the first embodiment;

FIG. 3 is a cross-sectional view taken along line 3-3′ in FIG. 2;

FIGS. 4A to 4E show parallel and anti-parallel states of an MTJ element according to the first embodiment, and the resistance distribution thereof;

FIG. 5 is a circuit diagram showing the memory cell array of the first embodiment;

FIGS. 6A and 6B are views for explaining the read operation of the MRAM of the first embodiment;

FIGS. 7A to 7D are views for explaining the write operation of the MRAM of the first embodiment;

FIGS. 8A to 8C are views for explaining the characteristics of the MTJ element according to the first embodiment;

FIG. 9 is a view for explaining the operation of the MRAM;

FIG. 10 is a circuit diagram showing a memory cell array according to a second embodiment;

FIGS. 11A and 11B are views for explaining a read operation according to the second embodiment;

FIGS. 12A and 12B are views for explaining a write operation according to the second embodiment;

FIG. 13 is a cross-sectional view taken along line 3-3′ in FIG. 2 and showing a memory cell array according to a first modification;

FIGS. 14A to 14D are conceptual diagrams showing the characteristics of an MTJ element according to the first modification;

FIGS. 15A to 15C are views for explaining the characteristics of the MTJ element according to the first modification;

FIG. 16 is a cross-sectional view taken along line 3-3′ in FIG. 2 and showing a memory cell array according to a third embodiment;

FIG. 17 shows resistances of an MTJ element according to the third embodiment;

FIGS. 18A to 18H are conceptual diagrams showing the characteristics of an MTJ element according to the third embodiment;

FIG. 19 shows the relationship between the states and resistances of the MTJ element according to the third embodiment;

FIGS. 20A to 20F are views for explaining the write operation of the MRAM of the third embodiment;

FIG. 21 shows the state transition of the MTJ element according to the third embodiment;

FIG. 22 is a block diagram showing an MRAM according to a second modification; and

FIG. 23 is a cross-sectional view taken along line 3-3′ and showing a memory cell array according to the second modification.

### DETAILED DESCRIPTION

In general, according to one embodiment, a variable resistance memory incorporates: a bit line extending in a first direction; first and second word lines extending in a second direction intersecting with the first direction; and a memory cell array including memory cells arranged in a matrix, each of the memory cells including a variable resistance element and at least one selective transistor, the variable resistance element being configured to store two-bit data using a change in resistance, the variable resistance element having an end connected to the bit line, and another end connected to a drain of the selective transistor, a source of the selective transistor being connected to a source line, a gate of the selective transistor being connected to the first word line. A first current or a second current being greater than the first current is applied to the variable resistance element using the selective transistor, to enable the data to be written or read.

Referring now to the accompanying drawings, embodiments will be described. However, it should be noted that the figures are schematic and conceptual, and hence that the dimensions and/or ratios employed therein are not always identical to the real ones. Further, even when the same elements are shown in different figures, the relationship between the dimensions and ratios may differ. In particular, the embodiments described below show exemplified devices and methods for realizing the technical idea of the invention, and the shapes, structures, arrangement, etc., of the structural elements do not limit the technical idea of the invention. The technical idea of the invention can be modified in various ways without departing from its scope. In the following descriptions, like reference numbers denote like elements, and duplication of explanation will be given only when necessary.

### First Embodiment

In a first embodiment, a description will be given, using an MRAM as an example of a variable resistance memory. The MRAM is provided with a storage element formed of a magnetic tunnel junction (MTJ) element that utilizes a magnetoresistive effect, and stores information (in the embodiment, four values of “11,” “10,” “01” and “00”) based on the magnetization arrangement of the MTJ element.

1. <Whole Configuration Example>

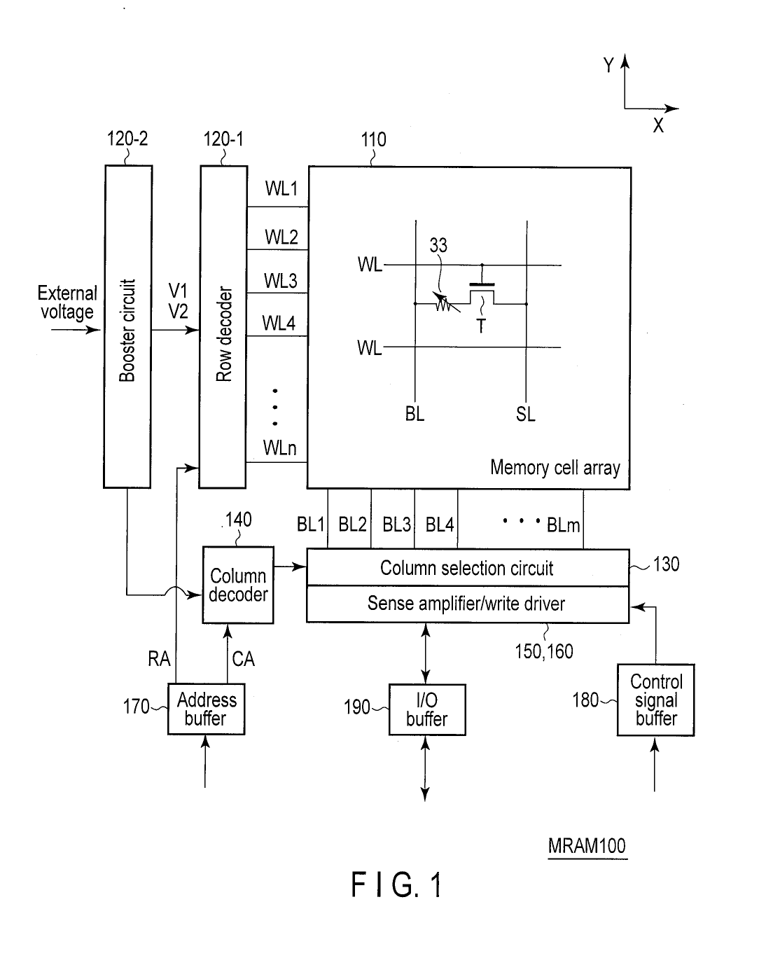

FIG. 1 is a block diagram showing the configuration of an MRAM 100 according to a first embodiment.

The MRAM 100 includes a memory cell array 110, a row decoder 120-1, a column selection circuit 130, a column decoder 140, a sense amplifier 150, a write driver 160, an address buffer 170, a control signal buffer 180 and a booster circuit 120-2.

The memory cell array 110 is formed of memory cells MC that include MTJ elements (magnetoresistive effect elements) 33 and are arranged in a matrix. The memory cell array 110 includes n word lines WL0 to WLn extending in a Y direction, and m bit lines BL0 to BLm extending in an X direction intersecting with the Y direction (n and m are natural numbers).

The row decoder 120-1 is connected to the word lines WL0 to WLn. The row decoder 120-1 selects one of the n word lines WL0 to WLn, based on a row address RA. In a second embodiment described later, two of 2n word lines are selected, and in a third embodiment described later, three of 3n word lines are selected.

A sense amplifier (read circuit) 150 and a write driver (write circuit) 160 are connected to the bit lines BL0 to BLm via the column selection circuit 130.

The column selection circuit 130 includes N-channel metal oxide semiconductor field effect transistors (MOSFETs) corresponding in number to, for example, the bit lines BL0 to BLm, and selects the one of the bit lines BL that is necessary for operation, in accordance with an instruction from the column decoder 140.

The column decoder 140 decodes a column address CA and sends the resultant decode signal to the column selection circuit 130.

The sense amplifier 150 detects the data stored in a selected memory cell, based on a read current Tread (hereinafter, Ir) that flows through a selected memory cell as a read target. The data read by the sense amplifier 150 is output to the outside via an input/output buffer (I/O buffer) 190.

The write driver 160 receives write data from the outside via an I/O buffer 190. The write driver 160 applies a write current +Iwrite (hereinafter, Iw) or a current −Iw to write predetermined data to a selected memory cell as a write target.

The address buffer 170 receives an address from the outside, and sends a row address RA to the row decoder 130, and a column address CA to the column decoder 140.

The control signal buffer 180 receives a control signal from the outside, and sends it to the sense amplifier 150 and the write driver 160. The control signal includes a write command, a read command, an erasure command, etc.

The booster circuit 120-2 receives an external voltage (e.g., a voltage VDD=1.5 V), and boosts this voltage VDD to a predetermined voltage. Further, the booster circuit 120-2 applies a voltage V1 (=voltage VDD) and a voltage V2 (>V1) to the row decoder 120-1 and the column decoder 140.

2. <Plan View of Memory Cell Array 110>

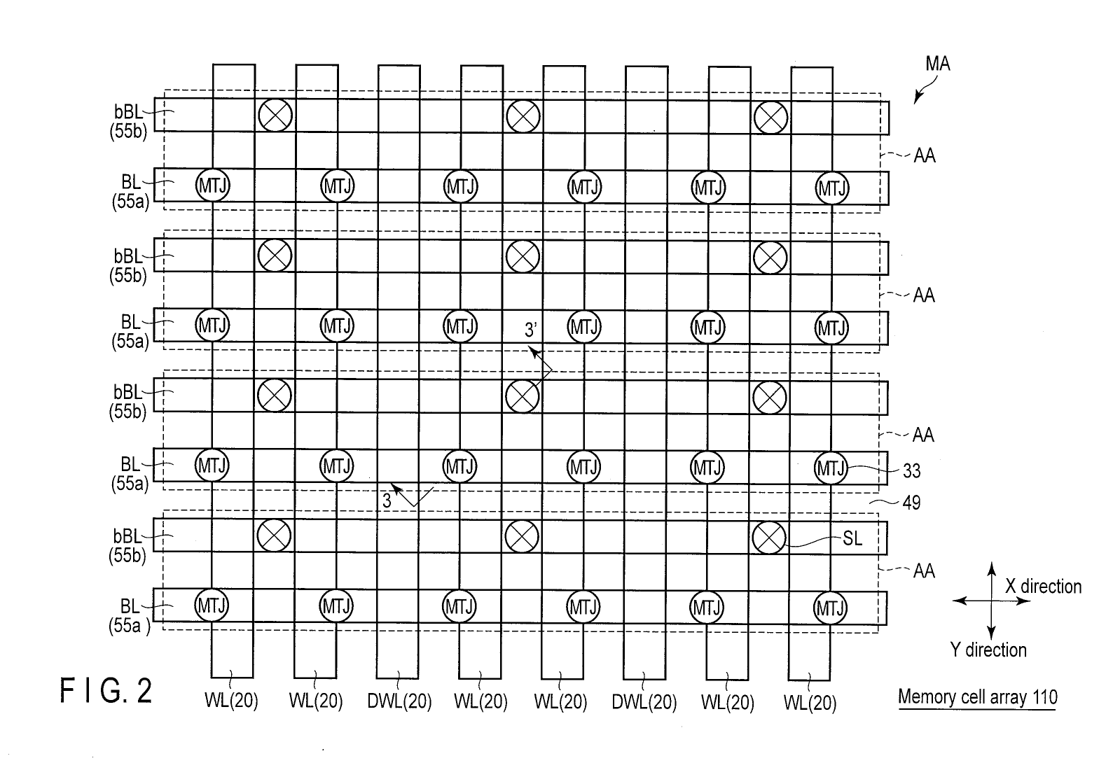

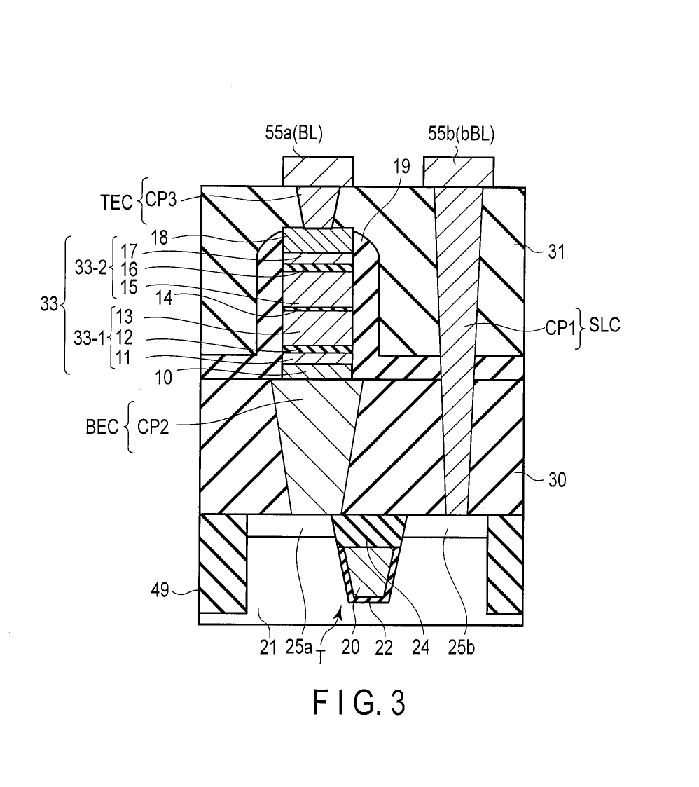

FIG. 2 is a plan view showing MTJ elements 33 of the embodiment arranged in an array. FIG. 3 is a cross-sectional view taken along line 3-3′ in FIG. 2. FIG. 3 also shows the cross sections of a source line 55b, as well as the cross sections of each MTJ element 33 and a bit line BL 55a.

As shown in FIGS. 2 and 3, the memory cell array 110 includes, for example, a plurality of word lines WL and a plurality of dummy word lines DWL, which extend in the Y direction, and a plurality of bit lines BL and a plurality of source lines SL (bBL in the figures), which extend in the X direction. The X and Y directions (axes) intersect with each other.

Further, combinations each including two word lines WL and one dummy word line DWL are alternately arranged in the X direction.

Furthermore, combinations each including one bit line BL and one source line SL are arranged in respective active areas AA and are alternately arranged in the Y direction.

Element isolation regions 49 are buried between respective pairs of adjacent active areas AA. Namely, the element isolation regions 49 and the active areas AA are alternately arranged in the Y direction.

The element isolation regions 49 are formed by, for example, shallow trench isolation (STI). The element isolation regions 49 are formed of an insulating material of a high embedding characteristic, such as a silicon nitride (SiN).

The cross-sectional view will now be explained.

As shown in FIG. 3, element isolation/insulation layers are provided on surface portions of a p-type semiconductor substrate (e.g., a silicon substrate) 21, which will serve as element isolation regions 49.

A selective transistor T formed of, for example, an n-channel metal oxide semiconductor field effect transistor (MOSFET) is provided as a switch element on the semiconductor substrate 21. The selective transistor T is formed by forming a recess in the semiconductor substrate 21 and filling the recess with a gate electrode 20 containing, for example, polysilicon.

More specifically, the selective transistor T includes a gate insulation layer 22, a gate electrode 20 and two diffusion layers 25a and 25b (a drain-side diffusion layer and a source-side diffusion layer).

The gate insulation layer 22 is formed on the lower inner surface of the wall defining the recess extending in the Y direction.

The gate electrode 20 is formed on the inner surface of the gate insulation layer 22 to fill the lower space of the recess. The gate electrode 20 corresponds to the word line WL. An insulation layer 24 formed of, for example, SiN is provided on the upper surface of the gate insulation layer 22 and the gate electrode 20 to fill the upper space of the recess.

The upper surface of the insulation layer 24 is level with the upper surface of the semiconductor substrate 21 (i.e., the upper surfaces of the diffusion layers 25a and 25b described later).

The diffusion layers 25a and 25b on the semiconductor substrate 21 are formed to surround the gate insulation layer 22, the gate electrode 20 and the insulation layer 24.

Further, as shown in FIG. 3, the element isolation regions 49 contact the diffusion layers 25a and 25b.

Furthermore, an interlayer insulation layer 30 is formed on the semiconductor substrate 21 (i.e., on the insulation layer 24 and the diffusion layers 25a and 25b).

A contact plug CP2 is formed in the interlayer insulation layer 30 on the diffusion layer 25a. The contact plug CP2 will be referred to as “the bottom electrode contact (BEC).”

The BEC is formed to contact a part of the upper surface of the diffusion layer 25a and a part of the upper surface of the insulation layer 24.

In other words, the BEC and the diffusion layer 25a partially overlap each other. This is because the BEC and the diffusion layer 25a (recess) differ in processing method. The planar shape of the BEC is, for example, a square. The BEC contains, for example, TiN, but is not limited to this.

A contact plug CP1 extends through the interlayer insulation layer 30 to the diffusion layer 25b. The contact plug CP1 also extends through an interlayer insulation film 31 described later, and has its upper surface kept in contact with a source line (55b (bBL) in FIGS. 2 and 3).

Moreover, the MTJ element 33 electrically connected to the BEC is formed in the interlayer insulation film 31.

The MTJ element 33 is formed in contact with the upper surface of the lower electrode 10. The planar shape of the MTJ element 33 is, for example, a circle, and is therefore formed cylindrical.

Although in the embodiment, the planar area of the MTJ element 33 is identical to that of the lower electrode 10, it is desirable that the former is smaller than the latter. As a result, the entire lower surface of the MTJ element 33 can be kept in contact with the upper surface of the lower electrode 10, which reduces the contact resistance.

The MTJ elements 33 each include an MTJ component 33-1 and an MTJ component 33-2.

To form each MTJ element 33, a storage layer 11, a tunnel barrier layer 12 and a reference layer 13, which cooperate to serve as the MTJ component 33-1, are sequentially formed in this order, and then a reference layer 15, a tunnel barrier layer 16 and a storage layer 17, which cooperate to serve as the MTJ component 33-2, are sequentially formed in this order with a nonmagnetic layer 14 interposed.

Regarding the storage layer 11 and the reference layer 13 stacked with the tunnel barrier layer 12 interposed therebetween, the order of stacking may be reversed. The same can be said of the storage layer 17 and the reference layer 15.

The storage layer 11 is a ferromagnetic layer having a variable magnetization direction, and has perpendicular magnetic anisotropy in which the magnetization direction is perpendicular or substantially perpendicular to the film surface (upper surface/lower surface). The term “variable magnetization direction” means that the magnetization direction varies in accordance with the direction of a predetermined write current.

Further, the term “substantially perpendicular” means that the direction of residual magnetization falls within 45°<θ≦90° with respect to the film surface.

The tunnel barrier layer 12 is a nonmagnetic layer and contains a nonmagnetic material, such as MgO. Alternatively, the tunnel barrier layer 12 may contain a metal oxide, such as Al₂O₃, MgAlO, ZnO or TiO.

The reference layer 13 is a ferromagnetic layer having a fixed magnetization direction, and has perpendicular magnetic anisotropy in which the magnetization direction is perpendicular or substantially perpendicular to the film surface. The term “fixed magnetization” means that the magnetization direction does not vary regardless of the direction of the predetermined write current. Namely, the reference layer 13 has a greater magnetization-direction-reversing-energy barrier than the storage layer 11.

Regarding the reference layer 15, the tunnel barrier layer 16 and the storage layer 17, the reference layer 15 and the storage layer 17 may be formed of the same material as that of the reference layer 13 and the storage layer 11, or of a material different from them. If these layers are formed of the same material, they are changed in film thickness, composition ratio, etc.

Because of the above, in the embodiment, the MTJ components 33-1 and 33-2 are set to have different resistances R and MR values.

Explanation of the cross-sectional view will be continued. An insulation film 19 formed of, for example, SiN is provided on the side walls (side surfaces) of the MTJ element 33 and on the surfaces (upper surfaces) of the BEC and the interlayer insulation film 30.

An upper electrode 18 is formed on the upper surface of the storage layer 17, and a contact plug CP3 (hereinafter referred to as “the TEC (top electrode contact)”), which has a bottom surface kept in contact with the upper surface of the upper electrode 18, and has an upper surface kept in contact with the bit line BL, is formed on the upper electrode 18.

Further, as described above, the contact plug CP1 extends through the interlayer insulation layers 30 and 31 to the upper surface of the diffusion layer 25b. The upper surface of the contact plug CP1 is connected to the source line (55b (bBL)).

Two of the three gate electrodes 20 adjacent in the X direction are electrically connected to MTJ elements and correspond to word lines WL, and the other one is electrically disconnected from MTJ elements and hence corresponds to a dummy word line DWL.

3. <Characteristics of MTJ Element 33>

3-1. Threshold Level

The threshold level of the MTJ element 33 will be described.

As aforementioned, each MTJ element 33 of the embodiment has two threshold levels. Assume here that the MTJ component 33-1 has a threshold level of Iw1, and the MTJ component 33-2 has a threshold level of Iw2.

Iw1 and Iw2 correspond to the write currents described later.

Namely, the magnetization direction of the storage layer 11 of the MTJ component 33-1 is reversed by the write current Iw1, thereby assuming a parallel or anti-parallel state with respect to the magnetization direction of the reference layer 13.

Similarly, the magnetization direction of the storage layer 17 of the MTJ component 33-2 is reversed by the write current Iw2, thereby assuming a parallel or anti-parallel state with respect to the magnetization direction of the reference layer 15.

Thus, each MTJ element 33 has a plurality of resistances corresponding to the states that can be assumed by the MTJ components 33-1 and 33-2. For instance, where each MTJ element 33 includes the MTJ component 33-1 and the MTJ component 33-2 as in the embodiment, it exhibits one of the four resistances.

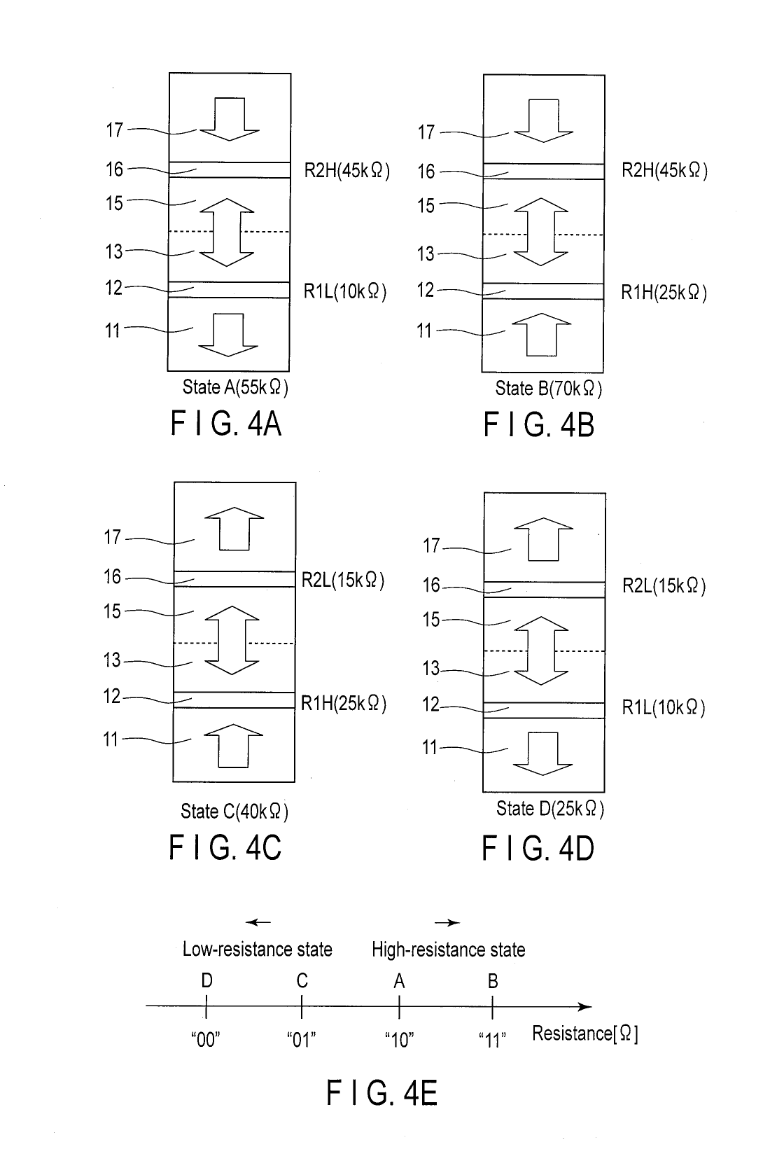

Referring now to FIGS. 4A to 4E, this will be described in detail.

3-2. Resistances of Each MTJ Element 33

The resistances of each MTJ element 33 will be described using FIGS. 4A to 4E. The resistance of the MTJ component 33-1 in a low resistance state, i.e., R1L, is set to 10 kΩ, and the MR value is set to 150%. The relationship between R1L, R1H and MR is given by

R1H=R1L(1+MR) (1)

Accordingly, the resistance of the MTJ component 33-1 in a high resistance state, i.e., R1H, is 25 kΩ from the equation (1).

Similarly, the relationship between R2L, R2H and MR is given by

R2H=R2L(1+MR) (2)

In this case, the resistance of the MTJ component 33-2 in a low resistance state, i.e., R2L, is set to 15 kΩ, and the MR value is set to 200%. The resistance of the MTJ component 33-2 in a high resistance state, i.e., R2H, is 45 kΩ from the equation (2). Each state will be described.

3-2-1. State A

FIG. 4A shows the MTJ element 33 in a state A.

As shown, in the state A, the storage layer 11 of the MTJ component 33-1 exhibits a parallel state (R1L (=10 kΩ) in FIG. 4) for the reference layer 13, and the storage layer 17 of the MTJ component 33-2 exhibits an anti-parallel state (R2H (=45 kΩ) in FIG. 4) for the reference layer 15.

Accordingly, the total resistance Rtotal of the MTJ element 33 in the state A is 55 kΩ. Assume here that the data held by the MTJ element 33 shifted to the state A is “10.”

3-2-2. State B

FIG. 4B shows the MTJ element 33 in a state B.

As shown in FIG. 4B, in the state B, the storage layer 11 of the MTJ component 33-1 and the storage layer 17 of the MTJ component 33-2 both exhibit an anti-parallel state (R1H (=25 kΩ) and R2H (=45 kΩ) in FIG. 4B) for the reference layers 13 and 15.

Accordingly, the total resistance Rtotal of the MTJ element 33 in the state B is 70 kn. Assume here that the data held by the MTJ element 33 shifted to the state B is “11.”

3-2-3. State C

FIG. 4C shows the MTJ element 33 in a state C.

As shown in FIG. 4C, in the state C, the storage layer 11 of the MTJ component 33-1 exhibits an anti-parallel state (R1H (=25 kΩ) in FIG. 4C) for the reference layer 13, and the storage layer 17 of the MTJ component 33-2 exhibits a parallel state (R2L (=15 kΩ) in FIG. 4C) for the reference layer 15.

Accordingly, the total resistance Rtotal of the MTJ element 33 in the state C is 40 kΩ). Assume here that the data held by the MTJ element 33 shifted to the state C is “01.”

3-2-4. State D

FIG. 4D shows the MTJ element 33 in a state D.

As shown in FIG. 4D, in the state D, the storage layer 11 of the MTJ component 33-1 and the storage layer 17 of the MTJ component 33-2 both exhibit a parallel state (R1L (=10 kΩ) and R2L (=15 kΩ) in FIG. 4D) for the reference layers 13 and 15.

Accordingly, the total resistance Rtotal of the MTJ element 33 in the state D is 25 kΩ. Assume here that the data held by the MTJ element 33 shifted to the state D is “00.”

As described above, the MTJ element 33 has a resistance corresponding to one of the four states, as is shown in FIG. 4E.

4. <Circuit Diagram of Memory Cell Array 110>

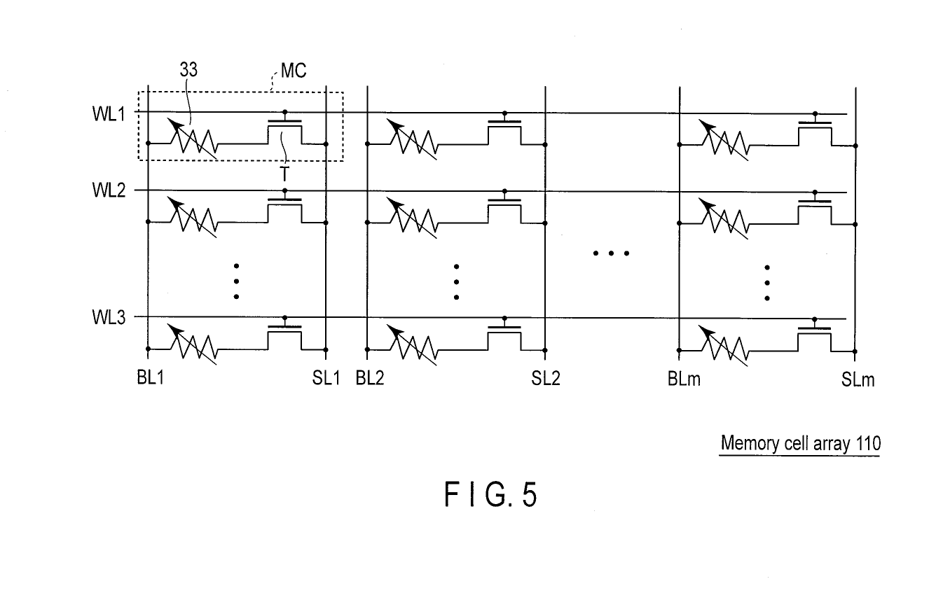

FIG. 5 is a circuit diagram showing the memory cell array 110. Each memory cell MC includes a single MTJ element 33 and a single selective transistor T. As the selective transistor T, an N-channel MOSFET, for example, is used. A description will now be given of the memory cell MC enclosed by the broken line.

One end of the MTJ element 33 is connected to, for example, a bit line BL1, and the other end of the same is connected to the drain of the selective transistor T. The source of the selective transistor T is connected to, for example, a source line SL1, and the gate of the selective transistor T is connected to a word line WL1.

Memory cells MC each formed of the MTJ element 33 and the selective transistor T are arranged in a matrix. In this section, the dummy word lines WL are omitted.

5. <Read Operation>

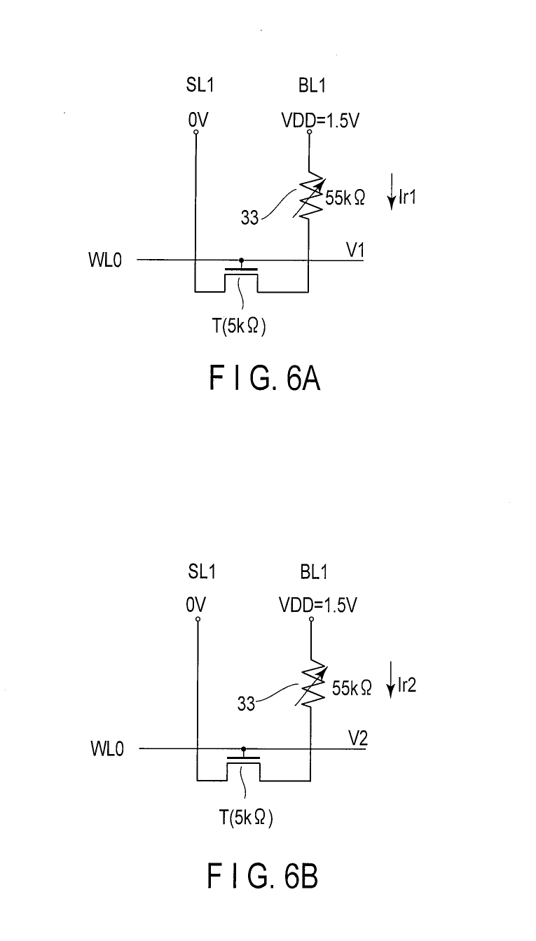

Referring then to FIGS. 6A and 6B, a read operation on the MTJ element 33 shifted to the state A will be described. In this case, the total resistance Rtotal is 55 kΩ. Specifically, FIG. 6A shows a normal read operation, and FIG. 6B shows a high-speed read operation.

Although in the following read operation, a read current Ir is applied from a bit line BL to a source line SL, a read current Ir passing from the selective transistor T to the MTJ element 33 may be applied to the memory cell MC during the read operation in order to reduce the disturbance that will occur during the read operation.

5-1. FIG. 6A

Firstly, the data held by the MTJ element 33 shown in FIG. 6A is read. In this case, the sense amplifier 150 sets, to 1.5 V, the voltage VDD applied to the bit line BL, while a source driver (not shown) sets the source line SL to a low level voltage (ground voltage VSS).

Further, the row decoder 120-1 sets the word line WL to a high level, i.e., transfers a voltage V1 to turn on the selective transistor T.

By this voltage control, in the selected memory cell MC, the read current Ir corresponding to the resistance of the MTJ element 33 is passed in the direction of the bit line BL→the MTJ element 33→the selective transistor T→the source line SL.

Assuming that if the resistance of the selective transistor T is 5 kΩ), the total resistance of this circuit is 60 kΩ, whereby a current I=25 μA is applied to the circuit as shown in FIG. 6.

By sensing the read current Ir1=25 μA, the sense amplifier 15 detects that the MTJ element 33 as a read target is in the state A, i.e., has a resistance of 55 kΩ.

A controller (not shown) may recognize the resistance (the assumed state) of the MTJ element 33, based on the sensing result of the sense amplifier 150.

Although the voltage VDD is used in the above-mentioned read operation, a current source may be used instead. In this case, the value of the current source must be lower than the threshold |Iw| of the MTJ element 33.

This is because if the current source value is greater than the threshold |Iw|, the storage layers will shift to an anti-parallel or a parallel state with respect to the reference layers, thereby changing the state of the MTJ element 33.

Thus, a read operation is performed while attention is being paid to the value of the current source. In this case, data reading is performed by detecting the voltage applied to the MTJ element 33.

In the above, a description has been given of an example of reading data from the MTJ element 33 in the state A. However, since the same can be said of the states B to D, no description will be given of these states.

5-2. FIG. 6B

It is assumed that the voltage VDD applied to the bit line BL1 is 1.5 V, the resistance of the selective transistor T is 5 kΩ), and the voltage applied to the word line WL is V2 (>V1). By this setting, the current driving force of the selective transistor T is increased to enable the sense amplifier SA to perform a higher-speed read operation than in the case of FIG. 6A. Further, since a current I of 25 μA is applied to the circuit of FIG. 6B, the sense amplifier 150 senses this current value to recognize that the MTJ element has been shifted to the state A.

6. <Write Operation>

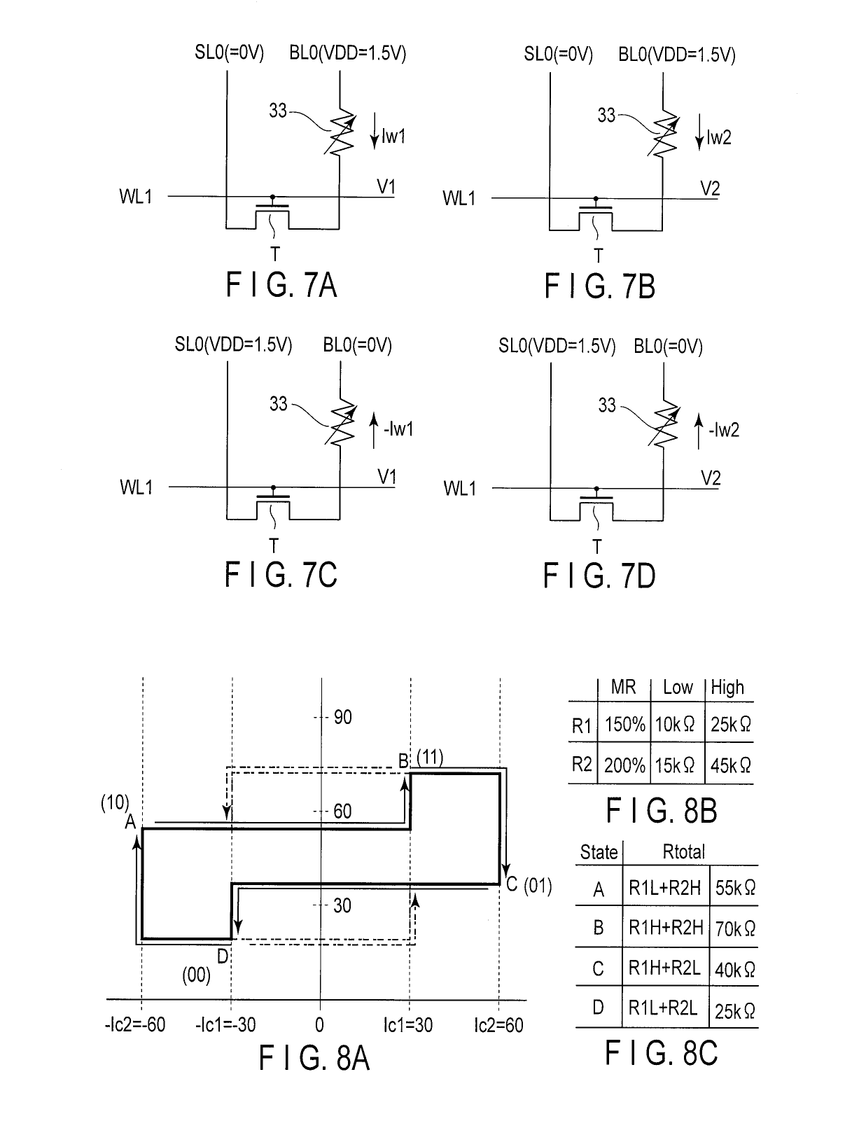

Referring then to FIGS. 7A to 7D and 8A to 8C, a write operation will be described. FIGS. 7A to 7D are conceptual views showing that write currents +Iw1 (or −Iw1) and +Iw2 (or −Iw2) are applied to the circuit.

Further, FIG. BA shows that shift to each of the states A to D is realized by a write operation. FIG. 8B shows the resistances R and MR values assumed when the MTJ components 33-1 and 33-2 are in the high and low resistance states. FIG. 8C shows the total resistances Rtotal of the MTJ element 33 that has been transitioned to the states A to D.

A description will now be given of a write operation in which the state is varied clockwise, beginning with the state A, and a write operation in which the state is varied counterclockwise, beginning with the state A.

Assume that the write current flowing from the reference layer 15 to the storage layer 11 is set as +Iw, and the write current flowing in the opposite direction is set as −Iw.

6.1. <State A→State B>

As shown in FIG. 7A, the write driver 160 applies the voltage VDD to the bit line BL0 and the source line SL driver grounds the source line SL0, with the voltage V1 applied to the word line WL. As a result, a write current Iw1 flows from the bit line BL0 to the source line SL0 (from the reference layer 15 to the storage layer 11).

Since as described above, the threshold of the storage layer 11 of the MTJ component 33-1 is Iw1, the magnetization direction of the storage layer 11 transitions from the parallel state to the anti-parallel state with respect to the reference layer 13.

Accordingly, as shown in FIGS. 8A and 8C, the MTJ element 33 transitions from the state A (R1L+R2H=55 kΩ) to the state B (R1H+R2H=70 kΩ), whereby it holds data “11.”

If a write current −Iw1 is applied to the MTJ element 33 by causing the source line SL driver (not shown) to apply the voltage VDD to the source line SL and causing the write driver 160 to ground the bit line BL as shown in FIG. 7D, the state B can be returned to the state A. In the embodiment below, when a current is flown in the opposite direction, this voltage relationship is satisfied.

6.2. <State B→State C>

Further, as shown in FIG. 7B, the write driver 160 applies the voltage VDD to the bit line BL1 and the source line SL driver grounds the source line SL, with the voltage V2 applied to the word line WL. As a result, a write current +Iw2 is applied to the MTJ element 33 from the bit line BL to the source line SL (from the reference layer 15 to the storage layer 11).

Since as described above, the threshold of the storage layer 17 of the MTJ component 33-2 is Iw2, the magnetization direction of the storage layer 17 transitions from the parallel state to the anti-parallel state with respect to the reference layer 15.

Accordingly, as shown in FIGS. 8A and 8C, the MTJ element 33 transitions from the state B (R1H+R2H=70 kΩ) to the state C (R1H+R2L=40 kΩ)), whereby it holds data “01.”

The reason why the resistance is reduced regardless of the same positive current when shift from the state B to the state C has been performed lies in that the magnetization direction of the storage layer 11 viewed from the reference layer 13 is opposite to that of the storage layer 17 viewed from the reference layer 15.

6.3. <State C→State D>

After that, as shown in FIG. 7D, an opposite-directional write current Iw2 (−Iw2 in the figure) is applied to the MTJ element 33 from the source line SL to the bit line BL (from the storage layer 11 to the reference layer 15).

Since as described above, the threshold of the storage layer 11 of the MTJ component 33-1 is Iw1, the magnetization direction of the storage layer 11 transitions from the parallel state to the anti-parallel state with respect to the reference layer 13.

Accordingly, as shown in FIGS. 8A and 8C, the MTJ element 33 transitions from the state C (R1H+R2L=40 kΩ) to the state D (R1L+R2L=25 kΩ), whereby it holds data “00.”

If the write current Iw1 is applied to the MTJ element 33 by causing the source line SL driver (not shown) to apply the voltage VDD to the source line SL and causing the write driver 160 to ground the bit line BL as shown in FIG. 7A, the state D can be returned to the state C as shown in FIGS. 8A and 8B.

6.4. <State D→State A>

Lastly, as shown in FIG. 7D, the write current Iw2 (−Iw2 in the figure) is applied to the MTJ element 33 from the source line SL to the bit line BL (from the storage layer 11 to the reference layer 15).

Since as described above, the threshold of the storage layer 17 is Iw2, the magnetization direction of the storage layer 17 transitions from the parallel state to the anti-parallel state with respect to the reference layer 15.

Accordingly, as shown in FIGS. 8A and 8C, the MTJ element 33 transitions from the state D (R1L+R2L=25 kΩ), to the state A (R1L+R2H=55 kΩ), whereby it holds data “01.”

Further, as shown in FIG. 8A, the state A cannot directly be shifted to the state D. In order to shift the MTJ element 33 from the state A to the state D, it is necessary to apply the write current Iw2 to the MTJ element 33 in the state A so as to once set the MTJ element 33 in the state C, and thereafter to execute the write operation described in the above item 6.3.

### Advantages of the First Embodiment

In the MRAM of the first embodiment, data reading and writing can be realized on the MTJ element 33 that can hold four-value data.

As described above, the MTJ element 33 of the embodiment is shifted to any one of the parallel and anti-parallel states by the write currents Iw1 and Iw2.

In the first embodiment, the booster circuit 120-2 generates the voltages V1 and V2 for the MTJ element 33. By controlling the current driving force of the selective transistor T1, the write current Iw1 (or the write current −Iw1) and the write current Iw2 (or the write current −Iw2) can be applied to the MTJ element 33 as shown in FIGS. 7A to 7D.

Further, in the read operation, since the voltages V1 and V2 can be transferred to the word line WL as shown in FIGS. 6A and 6B, a higher-speed read operation can be performed, as well as a normal read operation.

### Second Embodiment

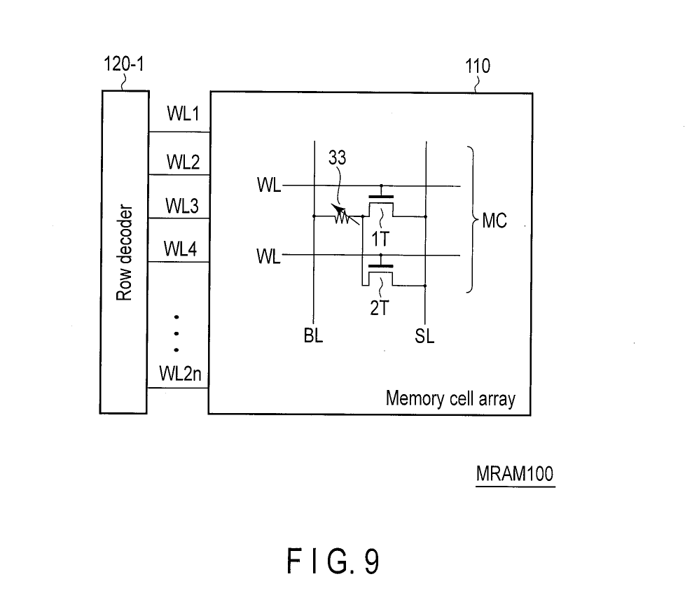

Referring then to FIG. 9, an MRAM 100 according to a second embodiment will be described. The MRAM 100 of the second embodiment differs from the first embodiment in that the former employs one additional selective transistor T which provides a current driving force equivalent to that obtained when the voltage V2 is transferred to the word line WL using the booster circuit 120-2. Since thus, the second embodiment employs an additional selective transistor T to increase the current driving force, it does not need the booster circuit 120-2. Only the different portion will be described.

1. <Whole Configuration Example>

FIG. 9 shows a memory cell array 110 and a row decoder 120-1. As shown, the memory cell array 110 and the row decoder 120-1 are connected to word lines WL (in FIG. 9, WL1, WL2, WL2n) twice the number of the word lines employed in the first embodiment.

Namely, each memory cell MC includes two selective transistors T. The two selective transistors T will be referred to as a selective transistor T1 and a selective transistor T2.

2. <Circuit Structure Example>

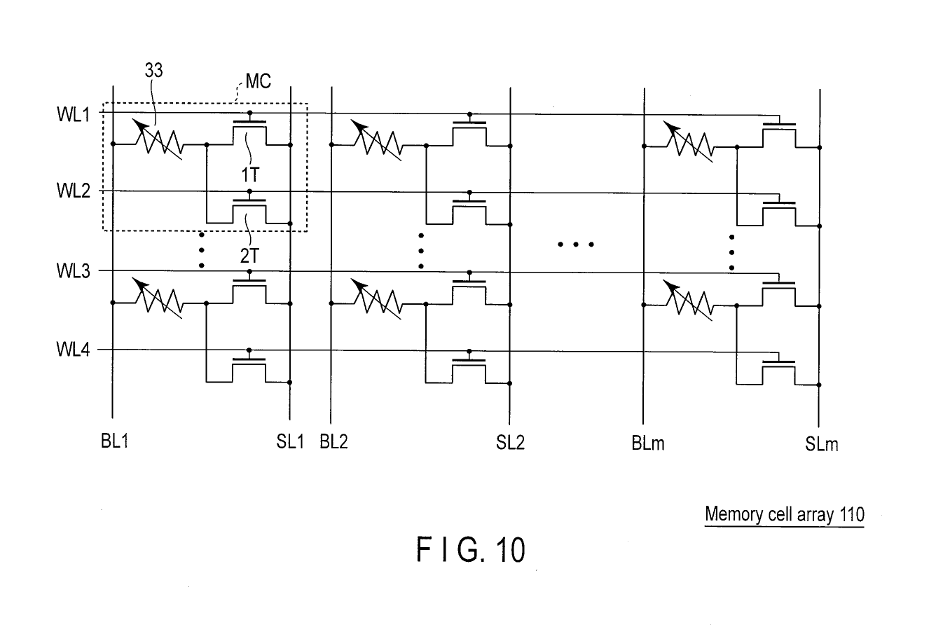

Referring to FIG. 10, the circuit structure of the MRAM 100 according to the second embodiment will be described. For instance, attention will be paid to a memory cell MC connected to word lines WL1 and WL2, a bit line BL1 and a source line SL1.

As shown, the word line WL1 is connected to the gate of the selective transistor T1, and the word line WL2 is connected to the gate of the selective transistor T2.

One end of the current path of each of the selective transistors T1 and T2 is connected to the MTJ element 33, and the other end of the current path is connected to the source line SL1.

The selective transistor T1 and/or T2 assumes an ON state in accordance with the voltage transferred to the word line WL. Thus, the write or read current applied to the MTJ element 33 is varied in accordance with the ON or OFF state of each of the selective transistors T1 and T2.

In the memory cell array 110 of the second embodiment, the memory cells MC are arranged in rows and columns.

3. <Read Operation>

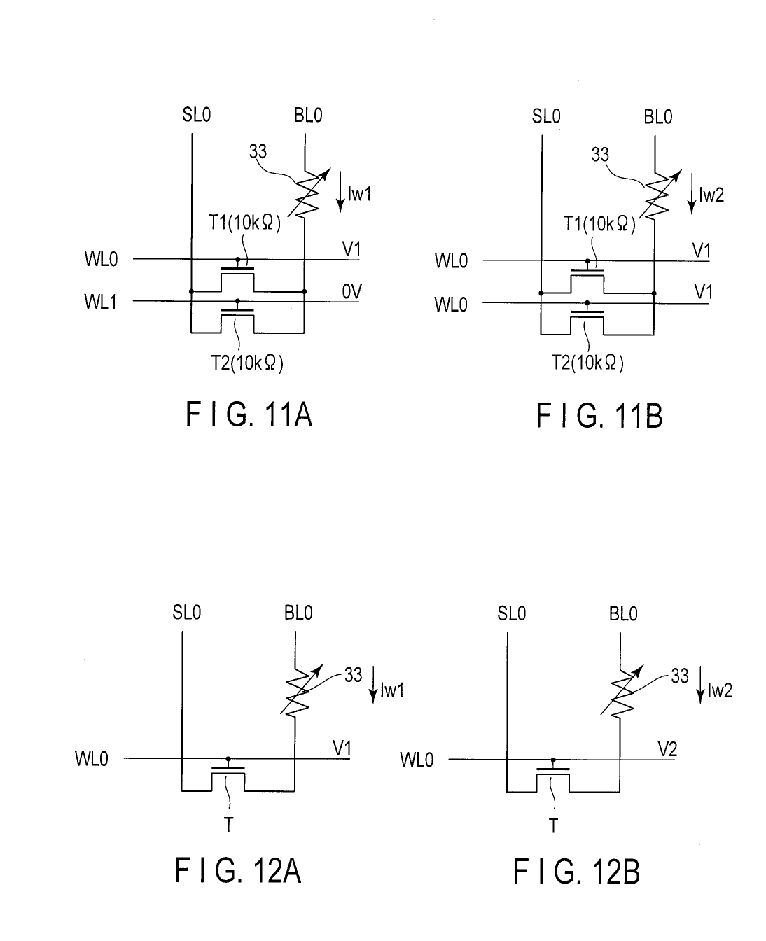

Referring then to FIGS. 11A and 11B, a read operation in the second embodiment will be described.

In the second embodiment, the resistance of the MTJ element 33 is set to 25 kΩ), and that of each of the selective transistors T1 and T2 is set to 10 kΩ.

Further, a voltage of 1.5 V is applied to the bit line BL, and the source line SL is grounded.

3.1. FIG. 11A: Normal Reading

As shown in FIG. 11A, the row decoder 120-1 transfers a voltage V1 to the word line WL0. The row decoder 120-1 transfers no voltage to the word line WL1.

As a result, the selective transistor T1 is turned on, while the selective transistor T2 is kept off.

At this time, the total resistance of the circuit is 35 kΩ, whereby a read current Ir of 43 μA is applied to the circuit of FIG. 11A.

In the normal reading, the sense amplifier 150 senses the current, thereby detecting that the MTJ element 33 is in the state A, i.e., the MTJ element 33 holds data “10.”

3.2. FIG. 11B: High-Speed Reading

As shown in FIG. 11B, the row decoder 120-1 transfers the voltage V1 to the word lines WL1 and WL2.

As a result, the selective transistors T1 and T2 are turned on and connected in parallel to each other, whereby the total resistance of the selective transistors T1 and T2 becomes ½.

Consequently, the total resistance of the circuit is 30 kΩ, and hence a read current Ir of 50 μA is applied to the circuit.

If in the high-speed reading, it is recognized that the read current is lower than the normal read current, it is detected that the MTJ element 33 has data “10,” when the above read current is read.

As described above, although the MTJ element 33 holds the same data, different currents are read therefrom between the normal reading and the high-speed reading, but the sense amplifier 150 can read the data held by the MTJ element 33.

In the above description, the MTJ element 33 holds data “10” (=25 kΩ) as an example. In the case of the other data items “00,” “01” and “11,” it is sufficient if currents corresponding to the data items are sensed in the same way as the above.

Further, the read currents 43 μA and 50 μA should be lower than the thresholds w1 and w2 of the MTJ element 33.

4. <Write Operation>

Referring now to FIGS. 12A and 12B, a write operation according to a second embodiment will be described. FIG. 12A is a conceptual view for explaining writing of a write current Iw1 to the MTJ element 33 by turning on the selective transistor T1, and FIG. 12B is a conceptual view for explaining writing of a write current Iw2 to the MTJ element 33 by turning on both the selective transistors T1 and T2.

4-1. Writing of Current Iw1

As shown in FIG. 12A, when a write current +Iw1 is applied to the MTJ element 33, the row decoder 120-1 transfers the voltage V1 to the word line WL1, and the write driver 160 applies the voltage VDD to the bit line BL.

As a result, the write current Iw1 is applied to the MTJ element 33, thereby shifting the reference layer 11 in the MTJ element 33 to a parallel or anti-parallel state. When a write current −Iw1 is applied as mentioned above, a potential difference may be provided in the opposite way between the bit line BL and the source line SL.

4-2. Writing of Current Iw2

As shown in FIG. 12B, when a write current Iw2 is applied to the MTJ element 33, the row decoder 120-1 transfers the voltage V1 to the word lines WL1 and WL2, and the write driver 160 applies the voltage VDD to the bit line BL.

As a result, the write current Iw2 is applied to the MTJ element 33, thereby shifting the reference layer 15 in the MTJ element 33 to a parallel or anti-parallel state. When a write current −Iw2 is applied, a potential difference may be provided in the opposite way between the bit line BL and the source line SL.

The states A to D assumed when the write operations have been performed are similar to those of the first embodiment. Therefore, no detailed description is given thereof.

### Advantages of the Second Embodiment

The MRAM 100 of the second embodiment has an advantage that the same current driving force as in the first embodiment can be obtained without using the booster circuit 120-2, as well as the advantages of the first embodiment.

This can be realized because the second embodiment employs the selective transistor T2 in addition to the selective transistor T1. The two selective transistors enable data writing to and reading from the MTJ element 33 using a single power supply, without the booster circuit 120-2.

Further, the MRAM 100 of the second embodiment can be made compact since the booster circuit 120-2 is not necessary.

Furthermore, although in the MRAM 100 of the second embodiment, the circuit area for the selective transistor T2 is required in each memory cell MC, stability is enhanced regardless of this requirement, since a current driving force is obtained by a plurality of selective transistors T.

The reason for the above will be described.

For generating the above-mentioned voltage V2, it is not necessary to employ a plurality of selective transistors T, if the booster circuit 120-2 is used. However, the boosted voltage V2 may become unstable, (1) if the operation of the booster circuit 120-2 is unstable, and/or (2) if the supplied external voltage is inconstant.

In addition, even where a desired voltage V2 is obtained, (3) it is necessary to consider variations in characteristics between individual selective transistors.

For the reasons (1) to (3), a desired current driving force may not be obtained by, for example, the selective transistor T shown in FIGS. 7A and 7B.

Such variations in characteristics between individual selective transistors T can be absorbed when a plurality of selective transistors T are simultaneously used, with the result that a substantially desired current driving force can be obtained.

[First Modification]

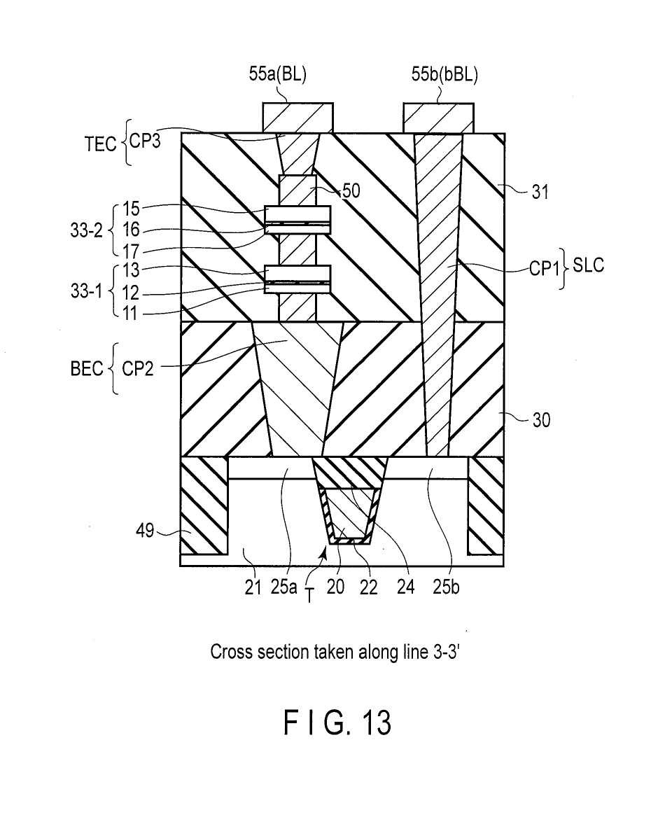

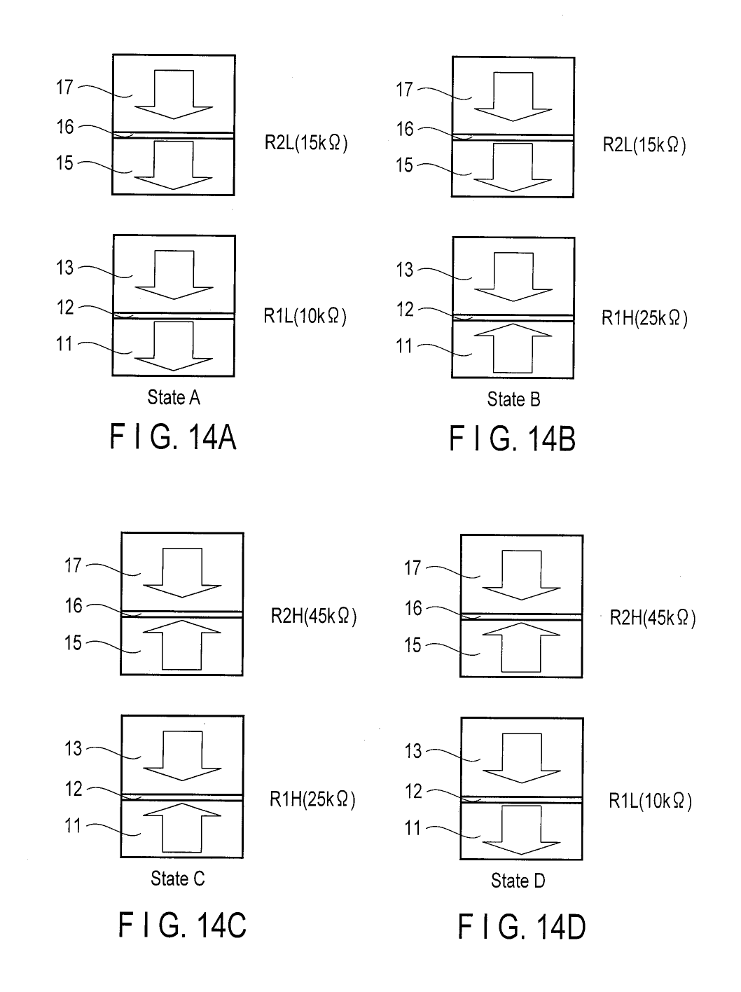

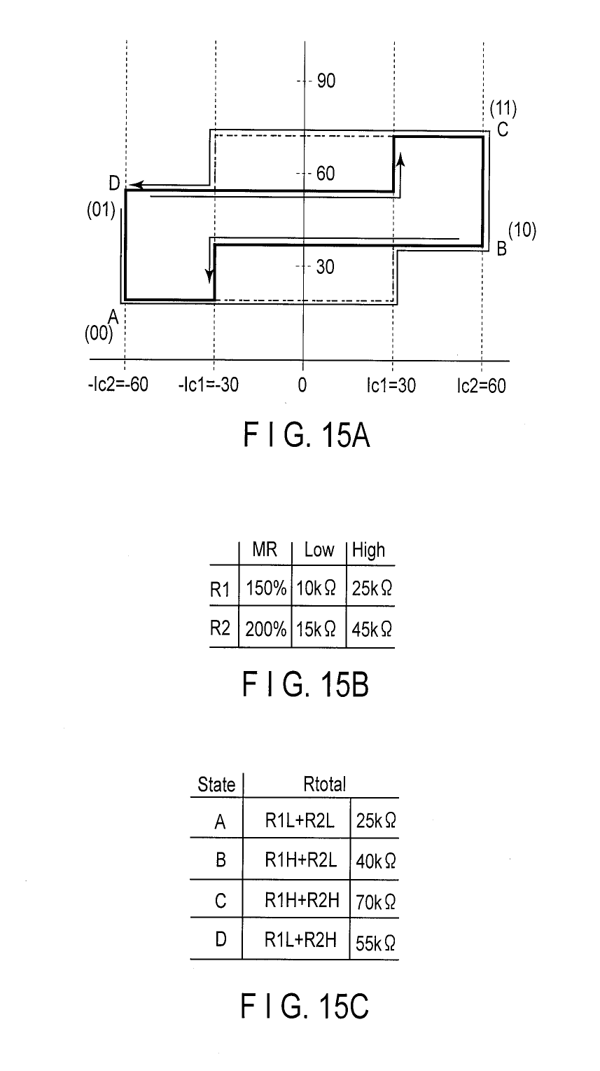

Referring then to FIG. 13, FIGS. 14A to 14D and FIGS. 15A to 15C, a description will be given of an MRAM 100 according to a modification (a first modification) of the first and second embodiments. The MRAM 100 of the first modification differs from the first and second embodiments in that in the former, the MTJ components 33-1 and 33-2 are formed separate from each other, and the arrangement of the reference layer 15 and the storage layer 17 is opposite between the MTJ components 33-1 and 33-2. This difference will be described.

1. <Structure Example>

FIG. 13 is a cross-sectional view taken along line 3-3′ in FIG. 2 and showing the MRAM of the modification. As shown, a contact plug 50 having its upper surface kept in contact with the TEC and its bottom kept in contact with the BEC is formed in the interlayer insulation film 31. Along the contact plug 50, the MTJ components 33-1 and 33-2 are formed separate from each other. The structure of each of the MTJ components 33-1 and 33-2 is the same as that of the first embodiment.

Namely, the MTJ component 33-1 includes the above-mentioned storage layer 11, tunnel barrier layer 12 and reference layer 13.

Similarly, the MTJ component 33-2 includes the above-mentioned reference layer 15, tunnel barrier layer 16 and storage layer 17.

2. <Resistance of MTJ Element 33>

Referring to FIGS. 14A to 14D, the resistance of the MTJ element 33 will be described. The resistances R1L and R1H of the MTJ component 33-1 in the low-resistance and high-resistance states, and the resistances R2L and R2H of the MTJ component 33-2 in the low-resistance and high-resistance states are the same as those in the first embodiment. Each state will be described.

2-1. State A

FIG. 14A shows the MTJ element 33 in the state A. As shown in FIG. 14A, the MTJ components 33-1 and 33-2 are both in the parallel state. Accordingly, the MTJ components 33-1 and 33-2 are in the low-resistance state and assume R1L (=10 kΩ) and R2L (=15 kΨ). As a result, the total resistance Rtotal of the MTJ element 33 in the state A is 25 kΩ.

2-2. State B

FIG. 14B shows the MTJ element 33 in the state B. As shown in FIG. 14B, the MTJ component 33-1 is in the anti-parallel state, and the MTJ component 33-2 is in the parallel state. Accordingly, the MTJ component 33-1 is increased to R1H (=25 kΩ). As a result, the total resistance Rtotal of the MTJ element 33 in the state B is 40 kΩ.

2-3. State C

FIG. 14C shows the MTJ element 33 in the state C.

As shown in FIG. 14C, the MTJ components 33-1 and 33-2 are both in the anti-parallel state. Accordingly, the MTJ components 33-1 and 33-2 are in the high-resistance state and assume R1H (=25 kΩ) and R2H (=45 kΩ). As a result, the total resistance Rtotal of the MTJ element 33 in the state C is 70 kΩ).

2-4. State D

FIG. 14D shows the MTJ element 33 in the state D. As shown in FIG. 14D, the MTJ component 33-1 is in the parallel state, and the MTJ component 33-2 is in the anti-parallel state. Accordingly, the resistances of the MTJ components 33-1 and 33-2 are R1H (=10 kΩ) and R2H (=45 kΩ). As a result, the total resistance Rtotal of the MTJ element 33 in the state B is 60 kΩ.

3. <Write Operation>

Referring now to FIGS. 15A to 15C, the write operation of the MTJ element 33 will be described. FIG. 15A is a conceptual view showing state transitions according to write operations. In this figure, the vertical axis indicates the resistance, and the horizontal axis indicates the current.

FIG. 15B shows the resistances R and MR values assumed when the MTJ components 33-1 and 33-2 are in the high and low resistance states. FIG. 15C shows the total resistances Rtotal of the MTJ element 33 that has been transitioned to the states A to D.

Further, the circuit diagrams for explaining the write operations are the same as those of FIGS. 7A to 7D, and will not be shown.

3-1. <State D→State A; Stage D→State C>

By applying the write current −Iw1 to the MTJ element 33, the state D is counterclockwise transitioned to the state A, and by applying the write current Iw2 to the MTJ element 33, the state D is clockwise transitioned to the state C.

3-1-1. Transition to State a

As shown in FIG. 15C, the MTJ element 33 in the state D is of a combination of the anti-parallel state and the parallel state (R1H+R2L). Accordingly, to make a transition to the state A, the write current −Iw1 is applied to the MTJ element 33. By thus transitioning the MTJ element 33 to the parallel state as shown in FIG. 14A, the state D is transitioned to the state A as shown in FIG. 15A, thereby transitioning the data held by the element 33 from “01” to “00.”

3-1-2. Transition to State C

To transition the MTJ element 33 to the state C, the write current +Iw2 is applied to the MTJ element 33. By thus transitioning one (the MTJ component 33-1) of the components from the parallel state to the anti-parallel state as shown in FIG. 14C, the state D is transitioned to the state C as shown in FIG. 15A. As a result, the data held by the MTJ element 33 is transitioned from “01” to “11.”

3-2. <State C→State D; Stage C→State B>

The state C can be counterclockwise transitioned to the state D, and be clockwise transitioned to the state B.

3-2-1. Transition to State D

As shown in FIG. 15C, the MTJ element 33 in the state C is of a combination of both anti-parallel states (R1H+R2H). Accordingly, to counterclockwise transition the state C to the state D as shown in FIG. 15A, the write current −Iw1 is applied to the MTJ element 33. By thus transitioning one (the MTJ component 33-1) of the components from the anti-parallel state to the parallel state as shown in FIG. 14D, the state C is transitioned to the state D as shown in FIG. 15A.

3-2-2. Transition to State B

To make a transition from the state C to the state B, the write current +Iw2 is applied to the MTJ element 33, thereby transitioning the magnetization direction of the storage layer 17 of the MTJ component 33-2 to the parallel state with respect to the reference layer 15 as shown in FIG. 14B. As a result, the state C is transitioned to the state B as shown in FIG. 15A.

3-3. <State B→State a; Stage B→State C>

By applying the write current −Iw1 to the MTJ element 33, the state B is clockwise transitioned to the state A, and by applying the write current +Iw2 to the MTJ element 33, the state B is counterclockwise transitioned to the state C.

3-3-1. Transition to State A

The MTJ element 33 in the state B is of a combination of the anti-parallel state and the parallel state. Accordingly, to make a transition to the state A, the write current −Iw1 is applied to the MTJ element 33 to thereby transitioning the magnetization direction of the storage layer 11 of the MTJ component 33-1 to the parallel state with respect to the reference layer 13 as shown in FIG. 14A. As a result, the state B is transitioned to the state A as shown in FIG. 15A.

3-3-2. Transition to State C

To transition the MTJ element 33 from the state B to the state C, the write current +Iw2 is applied to the MTJ element 33, thereby transitioning the magnetization direction of the storage layer 17 of the MTJ component 33-2 to the anti-parallel state with respect to the reference layer 15 as shown in FIG. 14C. As a result, the state. B is transitioned to the state C as shown in FIG. 15A.

3-4. <State A→State B>

By applying the write current +Iw1 to the MTJ element 33, the state A can be counterclockwise transitioned to the state B.

3-4-1. Transition to State B

To transition the MTJ element 33 to the state B, the write current +Iw2 is applied. By thus transitioning the magnetization direction of the storage layer 11 of the MTJ component 33-1 to the anti-parallel state with respect to the reference layer 15 as shown in FIG. 14B, the state A is transitioned to the state B as shown in FIG. 15A.

<Advantage of the First Modification>

The MRAM 100 of the first modification can provide the same advantage as that of the second embodiment. Namely, even if the MTJ components 33-1 and 33-2 are separate from each other, a desired current driving force can be obtained with the circuit area reduced, without the booster circuit 120-2.

Although in the first modification, each memory cell MC includes a single MTJ element 33 and selective transistors T1 and T2, the booster circuit 120-2 may be employed instead of the selective transistor T2.

### Third Embodiment

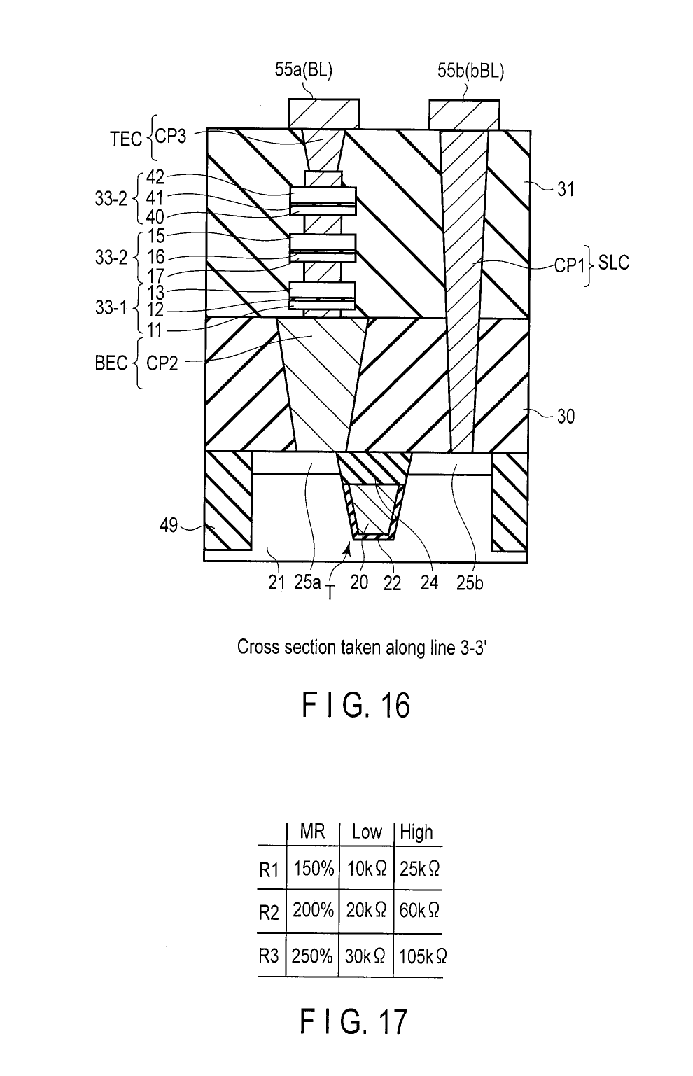

Referring now to FIGS. 16 to 21, an MRAM 100 according to a third embodiment will be described. In the third embodiment, the low-resistance state of an MTJ element 33 formed of three MTJ components, and a method of writing data to the MTJ element will be described.

In the third embodiment, a plurality of components included in the MTJ element 33 are separate from each other as in the first modification.

Further, in the third embodiment, the structures similar to those of the first modification will not be described.

1. <Structure Example>

As shown in FIG. 16, the MTJ element 33 of the third embodiment further includes an MTJ component 33-3. The MTJ component 33-3 is formed of a storage layer 40, a tunnel barrier layer 41 and a reference layer 42 stacked in this order from the bottom. The storage layer 40, the tunnel barrier layer 41 and the reference layer 42 are formed of the same materials as those in the above-described embodiments.

In the description below, the resistances of the MTJ components 33-1, 33-2 and 33-3 are denoted by R1, R2 and R3, respectively.

2. <Characteristics of MTJ Element 33>

2-1. Threshold of MTJ Element 33

Also in the MTJ component 33-3, the magnetization direction of the storage layer 40 assumes a parallel or an anti-parallel state with respect to the reference layer 42. In the following description, the current by which the magnetization direction of the storage layer 40 is changed, i.e., the threshold, is set to a current Iw3 (Iw2>Iw1). Namely, when the current Iw3 has been applied to the MTJ component 33-3, the magnetization direction of the storage layer is reversed and assumes the parallel or anti-parallel state with respect to the reference layer 42.

2-2. Resistances and MR Values of MTJ Components 33-1 to 33-3

Referring to FIG. 17, the resistances of the MTJ components 33 according to the third embodiment will be described. This figure shows the relationship between the resistances R1 to R3, the MR values and the resistances (R1L, R1H) of the MTJ components 33 in the low-resistance and high-resistance states.

As shown in FIG. 17, the MR value of the MTJ component 33-1 is 150%. Accordingly, the resistance R1L of this component in the low-resistance state is 10 kΩ, and the resistance R1H of this component in the high-resistance state is 25 kΩ, from the aforementioned equation (1).

Similarly, since the MR value of the MTJ component 33-2 is 200%, the resistance R2L of this component in the low-resistance state is 20 kΩ, and the resistance R2H of this component in the high-resistance state is 60 kΩ.

Further, since the MR value of the MTJ component 33-3 is 250%, the resistance R3L of this component in the low-resistance state is 30 kΩ, and the resistance R3H of this component in the high-resistance state is 105 kΩ. Since thus, each of the MTJ components 33-1 to 33-3 can exhibit two resistances, the whole MTJ element 33 can exhibit eight resistances. A description will be given of the possible states the MTJ element 33 and the total resistance of the MTJ element 33 in each state.

2-3. Total Resistance of MTJ Element 33

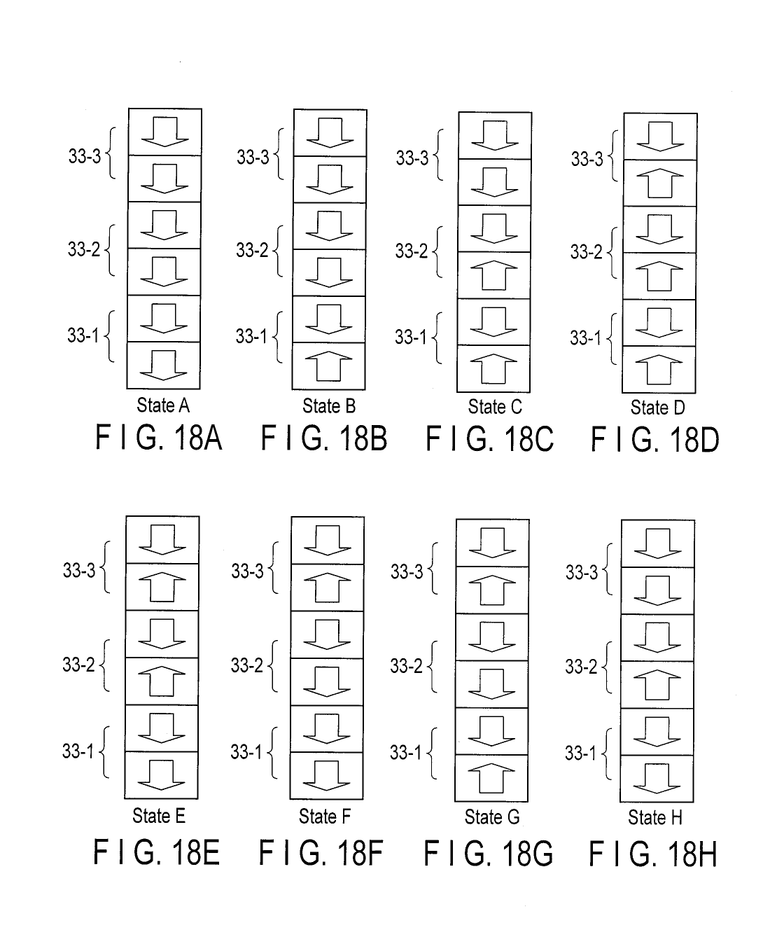

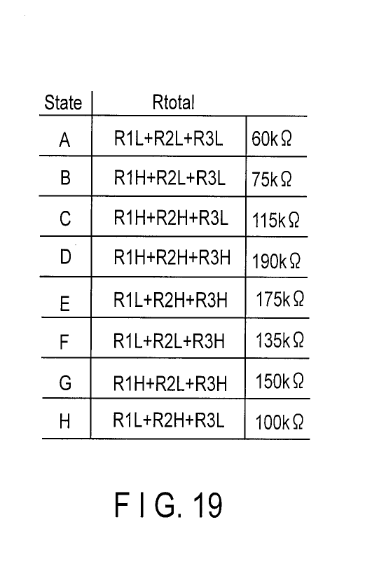

Referring then to FIGS. 18A to 18H and 19, the total resistance of the MTJ element 33 in each state will be described.

2-3-1. State A

As shown in FIG. 18A, in the state A, all MTJ components 33-1 to 33-3 are in the low-resistance state. Namely, as shown in FIG. 19, the total resistance Rtotal of the MTJ element 33 in the state A is R1L+R2L+R3L=60 kΩ.

2-3-2. State B

As shown in FIG. 18B, in the state B, the MTJ component 33-1 is in the high-resistance state, and the MTJ components 33-2 and 33-3 are in the low-resistance state. Namely, as shown in FIG. 19, the total resistance Rtotal of the MTJ element 33 in the state B is R1H+R2L+R3L=75 kΩ.

Since similar things can be said of the states C to H, a brief description will be given thereof.

2-3-3. States C to H

In the state C, the total resistance is 115 kΩ as shown in FIGS. 18C and 19, and in the state D, the total resistance is 190 kΩ as shown in FIGS. 18D and 19. In the state E, the total resistance is 175 kΩ as shown in FIGS. 18E and 19, and in the state F, the total resistance is 135 kΩ as shown in FIGS. 18F and 19. In the state G, the total resistance is 150 kΩ as shown in FIGS. 18G and 19, and in the state H, the total resistance is 100 kΩ as shown in FIGS. 18H and 19.

3. <Write Method>

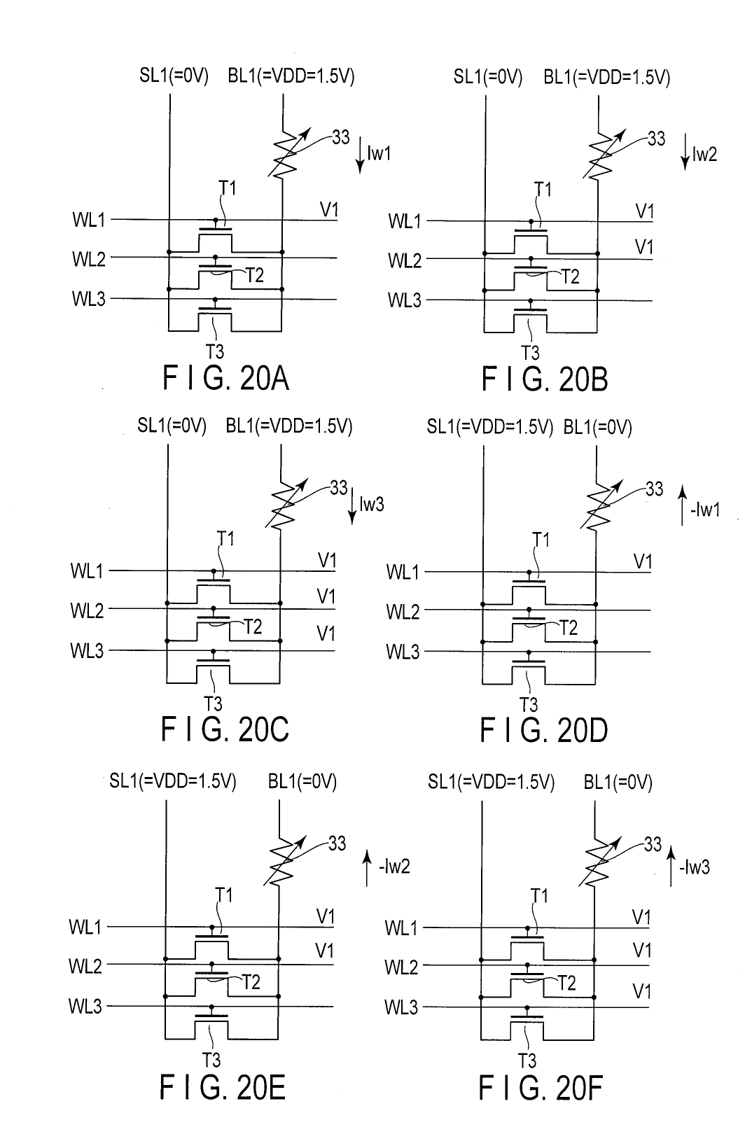

A write method used in the MRAM 100 of the third embodiment will be described with reference to FIGS. 20A to 20F.

As described above, in the third embodiment, yet another selective transistor is employed to apply a further write current Iw3. Namely, in the MRAM 100 of the third embodiment, each memory cell MC is formed of a single MTJ element 33 and three selective transistors. The third selective transistor is set as a selective transistor T3.

As shown, when a write current Iw1 is applied to the MTJ element 33, the row decoder 120-1 turns on the selective transistor t1 to transfer the voltage V1 to the word line WL1, while the sense amplifier 150 transfers the voltage VDD to the bit line BL. At this time, a source line SL driver (not shown) grounds the source line SL. As a result, the write current Iw1 is flown in the direction indicated in FIG. 20A.

The same can be said of the cases where the write currents Iw2 and Iw3 are applied to the MTJ element 33. Namely, when the write current Iw2 is applied to the MTJ element 33, the row decoder 120-1 transfers the voltage V1 to the word lines WL1 and WL2, as is shown in FIG. 20B. Similarly, when the write current Iw3 is applied to the MTJ element 33, the row decoder 120-1 transfers the voltage V1 to the word lines WL1, WL2 and WL3, as is shown in FIG. 20C.

4. <State Transitions of MTJ Element 33 Caused by Write Operations>

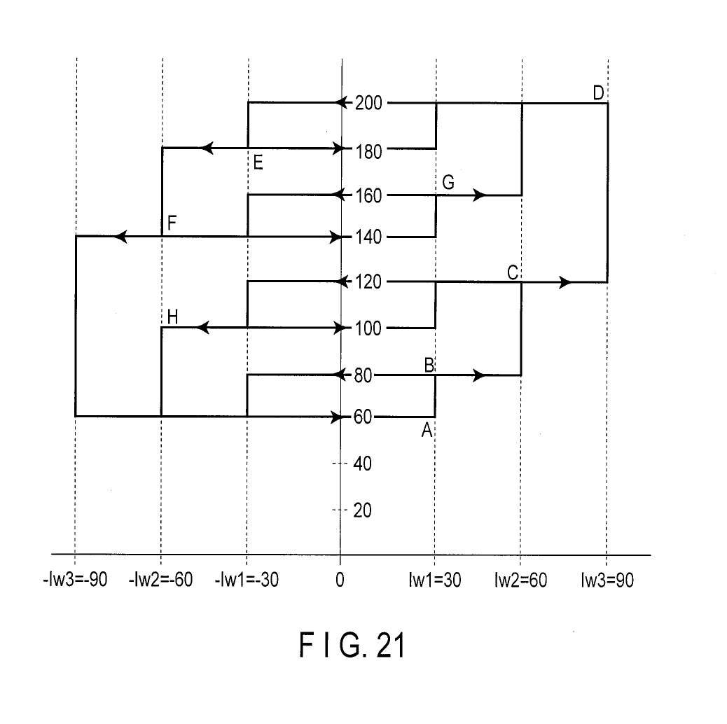

Referring to FIG. 21, state transitions of the MTJ element 33 caused by write operations will be described. In FIG. 21, the vertical axis indicates the resistance of each state (states A to H), and the horizontal axis indicates the write current. For facilitating the description, only write operations causing state transitions of state A→state B→ . . . →state H will be described.

4-1. State A→State B

To make a transition from the state A to the state B, the write current +Iw1 is applied to the MTJ element 33. As a result, the magnetization direction of the storage layer 11 of the MTJ component 33-1 transitions from the parallel state to the anti-parallel state with respect to the reference layer 13 (see FIGS. 18B and 19).

At this time, if a write current −Iw1 is applied to the MTJ element 33, a transition from the state B to the state A is made as shown in FIG. 21.

4-2. State B→State C

To make a transition from the state B to the state C, the write current +1w2 is applied to the MTJ element 33. As a result, the magnetization direction of the storage layer 17 of the MTJ component 33-2 transitions to the anti-parallel state with respect to the reference layer 15 (see FIGS. 18C and 19).

At this time, if a write current −Iw2 is applied to the MTJ element 33, a transition from the state C to the state B is made as shown in FIG. 21.

4-3. State C→State D

To make a transition from the state C to the state D, the write current +Iw3 (90 RA in FIG. 21) is applied to the MTJ element 33. As a result, the magnetization direction of the storage layer 40 of the MTJ component 33-3 transitions to the anti-parallel state with respect to the reference layer 42 (see FIGS. 18D and 19).

4-4. State D→State E

To make a transition from the state D to the state E, the write current Iw1 is applied to the MTJ element 33 in the opposite direction (i.e., the write current −Iw1 is applied to the MTJ element 33). As a result, the magnetization direction of the storage layer 40 of the MTJ component 33-3 transitions to the anti-parallel state with respect to the reference layer 42 (see FIGS. 18E and 19). Namely, a transition from the state D to the state E is made.

At this time, if the write current +Iw1 is applied to the MTJ element 33, a transition from the state E to the state D is made as shown in FIG. 21.

4-5. State E→State F

To make a transition from the state E to the state F, the write current Iw2 is applied to the MTJ element 33 in the opposite direction as described above (i.e., the write current −Iw2 is applied to the MTJ element 33). As a result, the magnetization direction of the storage layer 17 of the MTJ component 33-2 transitions to the parallel state with respect to the reference layer 15 (see FIGS. 18F and 19). Namely, a transition from the state E to the state F is made.

At this time, if the write current +Iw2 is applied to the MTJ element 33, a transition from the state F to the state E is made as shown in FIG. 21.

4-6. State F→State G

To make a transition from the state F to the state G, the write current +Iw1 is applied to the MTJ element 33. As a result, the magnetization direction of the storage layer 17 of the MTJ component 33-2 transitions to the parallel state with respect to the reference layer 15 (see FIGS. 18G and 19). Namely, a transition from the state E to the state F is made.

At this time, if the write current +Iw2 is applied to the MTJ element 33, a transition from the state F to the state E is made as shown in FIG. 21.

4-7. State A→State H

Since a transition from the state G to the state H is impossible, it is necessary to make a transition from the state A in order to realize a transition to the state H. More specifically, the write current Iw2 is applied to the MTJ element 33 in the opposite direction as described above (i.e., the write current −Iw2 is applied to the MTJ element 33). As a result, the magnetization direction of the storage layer 17 of the MTJ component 33-2 transitions to the anti-parallel state with respect to the reference layer 15 (see FIGS. 18H and 19).

At this time, if the write current +Iw2 is applied to the MTJ element 33, a transition from the state H to the state A is made as shown in FIG. 21.

Also at this time, not only the return from the state H to the state A, but also a transition to the state C are possible.

### Advantages of the Third Embodiment

The MRAM 100 of the third embodiment can has the same advantages as the second embodiment. Normally, it is necessary to generate a voltage V3 from the voltage V1 using the booster circuit 120-2. However, since the third embodiment employs the selective transistor T3, the current driving force can be amplified without the booster circuit 120-2.

Further, since the booster circuit 120-2 is not needed, the circuit area can be reduced, as in the second embodiment.

[Second Modification]

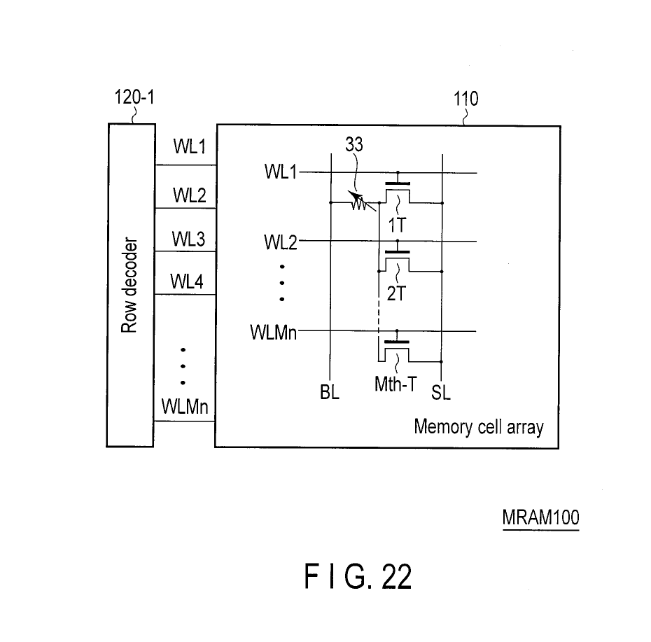

Referring to FIGS. 22 to 24, an MRAM 100 according to a modification (hereinafter, “the second modification”) of the third embodiment will be described. The second modification employs a structure in which the MTJ element 33 includes M (M is a natural number not smaller than 4) layers each formed of a storage layer, a tunnel barrier layer and a reference layer.

In the third modification, since no booster circuit 120-2 is employed, M selective transistors T are used in each memory cell MC. This structure will be described.

1. <Structure Example>

FIG. 22 shows a memory cell array 110 according to the second modification, and a row decoder 120-1 for controlling the voltage of the word lines WL.

As shown in FIG. 22, each memory cell MC according to the second modification includes M selective transistors T and a single MTJ element 33.

Accordingly, if the memory cell array 110 includes N rows of memory cells MC, the row decoder1 120-1 is connected to the memory cell array 110 by (N×M) word lines WL in total.

For instance, the memory cells MC of the first row are connected to word lines WL1 to WLM, and the memory cells MC of the second row are connected to word lines WL(M+1) to WL2M.

2. <Cross Section of MTJ Element 33>

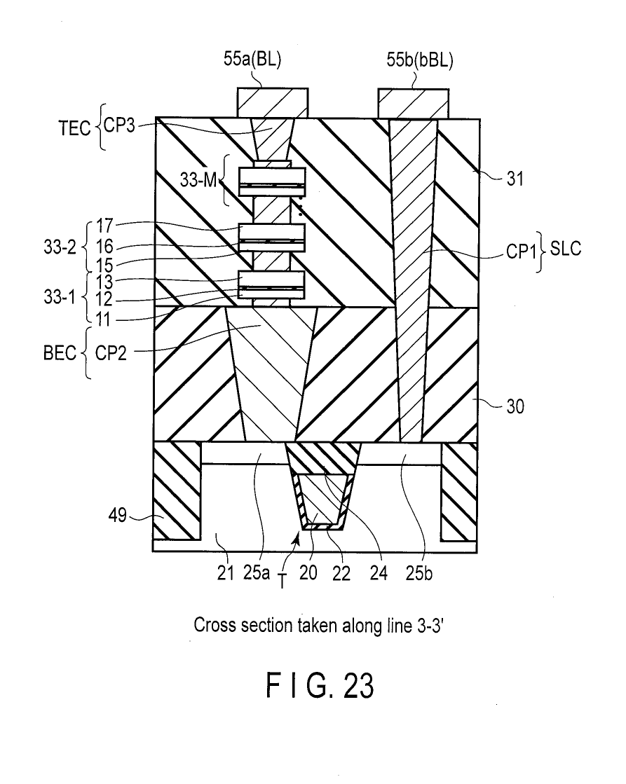

FIG. 23 is a cross-sectional view taken along line 3-3′, and showing the MTJ element 33 of this modification. As described above, in this modification, the MTJ element 33 is formed of M storage layers, M tunnel barrier layers, and M reference layers.

Namely, the MTJ element 33 includes MTJ components 33-1, 33-2, . . . , 33-M.

3. <Characteristics of MTJ Element 33>

3-1. MR Value and Resistance of MTJ Element 33

The MTJ components 33-1 to 33-M may be formed of the same materials as those in the first embodiment, or materials different from those in the first embodiment. For instance, if the same materials as those in the first embodiment are used, the MR value, the resistance, etc., are changed by changing the storage and reference layers in thickness or composition ratio. As a result, the MTJ element 33 has a plurality of MR values (M MR values) and a plurality of total resistances Rtotal (M total resistances Rtotal).

3-2. Thresholds of MTJ Element 33

The MTJ element 33 of the second modification has a threshold distribution, i.e., has M thresholds defined by the currents Iw1, Iw2, Iw3, . . . , IwM.

If, for example, a write current Iwt (4≦t≦M, t: a natural number) is applied to the t^{th} storage layer or reference layer, a transition to the parallel or anti-parallel state is made.

4. Write Operation

The MTJ element 33 is transitioned to the respective states when the write currents Iw1 to IwM or the opposite-directional write currents Iw1 to IwM have been applied to the MTJ element 33 (although write operations on the MTJ element 33 will not be described in detail).

<Advantages of the Second Modification>

The MRAM according to the second modification can have the same advantages as those of the above-described embodiments. Namely, in this modification, the circuit area can be reduced, and at the same time, the same current driving force as in the above-described embodiments can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A variable resistance memory comprising:
a bit line extending in a first direction;
a first word line extending in a second direction intersecting with the first direction; and
a memory cell array including memory cells arranged in a matrix, each of the memory cells including a variable resistance element and at least one selective transistor, the variable resistance element being configured to store two-bit data using a change in resistance, the variable resistance element having an end connected to the bit line, and another end connected to a drain of the selective transistor, a source of the selective transistor being connected to a source line, a gate of the selective transistor being connected to the first word line,
wherein
a first write current and a second write current being greater than the first write current are selectively applied to the variable resistance element using the selective transistor, to enable the data to be written; and
a first read current and a second read current being greater than the first read current are selectively applied to the variable resistance element using the selective transistor, to enable the data to be read.

2. The variable resistance memory of claim 1, wherein the second write current and the second read current are obtained by boosting a current driving force of the selective transistor, or by adding the first read current and the first write current.

3. The variable resistance memory of claim 1, further comprising a booster circuit configured to apply, to the first word line, a first voltage based on an external voltage, or a second voltage obtained by boosting the external voltage.

4. The variable resistance memory of claim 1, wherein
the variable resistance element includes a first variable resistance component formed on a semiconductor substrate, and a second variable resistance component formed on the first variable resistance component;
the first variable resistance component is formed by stacking, from a bottom, a first storage layer, a first tunnel barrier layer and a first reference layer in an order mentioned; and
the second variable resistance component is formed by stacking, from a bottom, a second storage layer, a second tunnel barrier layer and a second reference layer in an order mentioned.

5. The variable resistance memory of claim 4, wherein
the first storage layer and the second storage layer differ in composition ratio or thickness; and
the first reference layer and the second reference layer differ in composition ratio or thickness.

6. The variable resistance memory of claim 4, wherein
each of the first variable resistance component and the second variable resistance component is configured to transition to a low-resistance state and a high-resistance state; and
each of the first variable resistance component and the second variable resistance component is configured to exhibit different resistances in the low-resistance state and the high-resistance state.

7. The variable resistance memory of claim 4, wherein
the first variable resistance component is configured to transition to a low-resistance state and a high-resistance state when receiving the first write current; and
the second variable resistance component is configured to transition to the low-resistance state and the high-resistance state when receiving the second write current.

8. The variable resistance memory of claim 1, wherein
the at least one selective transistor includes a first selective transistor and a second selective transistor, a drain and a source of the first selective transistor being connected in common to a drain and a source of the second selective transistor, respectively; and
in each of the memory cells, a gate of the first selective transistor is connected to the first word line, and a gate of the second selective transistor is connected to a second word line extending parallel to the first word line.

9. The variable resistance memory of claim 8, further comprising a row decoder configured to apply a first voltage based on an external voltage to the first and second word lines,
wherein
the row decoder applies the first voltage to the first word line to apply a first write current to the variable resistance element; and
the row decoder applies the first voltage to the first and second word lines to apply a second write current to the variable resistance element.

10. The variable resistance memory of claim 1, further comprising:
a sense amplifier configured to read the data from the variable resistance element; and
a source-line driver connected to the source line,
wherein
when reading the data, the sense amplifier applies a selection potential or a constant current to the bit line;
the source-line driver grounds the source line; and
the sense amplifier read the data by detecting a current applied to the bit line or a voltage applied to the variable resistance element.

11. The variable resistance memory of claim 6, wherein
the high-resistance state and the low-resistance state of the first variable resistance component are set by a magnetization direction of the first storage layer with respect to the first reference layer; and
the high-resistance state and the low-resistance state of the second variable resistance component are set by a magnetization direction of the second storage layer with respect to the second reference layer.

12. The variable resistance memory of claim 6, wherein
each of the first and second variable resistance components is configured to transition to one of a parallel state indicating the low-resistance state, and an anti-parallel state indicating the high-resistance state, in accordance with the magnetization direction;
resistances exhibited by the variable resistance element include:
a resistance corresponding to a first state in which the first and second variable resistance components are both in the parallel state;
a resistance corresponding to a second state in which the first variable resistance component is in the anti-parallel state and the second variable resistance component is in the parallel state;
a resistance corresponding to a third state in which the first variable resistance component is in the parallel state and the second variable resistance component is in the anti-parallel state; and
a resistance corresponding to a fourth state in which the first and second variable resistance components are both in the anti-parallel state.

13. A read method for use in a variable resistance memory, comprising:
applying a first voltage to a bit line connected to an end of the variable resistance element;
applying a second voltage to a gate of at least one selective transistor, a current path of the selective transistor having an end connected to another end of the variable resistance element, and having another end connected to a source line; and
detecting a read current flowing through the variable resistance element and corresponding to the second voltage to read data,
wherein the read current is a first read current, or a second read current greater than the first read current.

14. The read method of claim 13, wherein when the second read current is applied to the variable resistance element, the second read current is obtained by boosting the second voltage to boost a current driving force of the selective transistor, or by adding currents output from the selective transistor and corresponding to the second voltage.

15. The read method of claim 13, further comprising boosting the second voltage to generate a third voltage greater than the second voltage,
wherein
the at least one selective transistor includes a first selective transistor; and
the third voltage is applied to a gate of the first selective transistor to detect a current flowing through the variable resistance element and corresponding to the third voltage to read the data.

16. The read method of claim 13, further comprising applying the second voltage to a gate of a second selective transistor, a current path of the second selective transistor having an end connected to the source line, and another end connected to the variable resistance element,
wherein a current flowing through the variable resistance element is detected to read the data.

17. A write method for use in a variable resistance memory, comprising:
applying a first voltage to a bit line connected to an end of a variable resistance element which holds two-bit data;
applying a second voltage to a gate of at least one selective transistor, a current path of the selective transistor having an end connected to another end of the variable resistance element, and having another end connected to a source line; and
applying a current corresponding to the second voltage to the variable resistance element to write the data to the variable resistance element,
wherein the write current is a first write current, or a second write current greater than the first write current.

18. The write method of claim 17, wherein when the second write current is applied to the variable resistance element, the second write current is obtained by boosting the second voltage to increase a current driving force of the selective transistor, or by adding currents output from the selective transistor and corresponding to the second voltage.

19. The write method of claim 17, further comprising generating a third voltage greater than the second voltage,
wherein
the third voltage is transferred to the gate of the selective transistor to apply the current corresponding to the third voltage to the variable resistance element, to write the data to the variable resistance element.

20. The write method of claim 17, wherein
the at least one selective transistor includes a first selective transistor and a second selective transistor;
further comprising:
applying the second voltage to a gate of the first selective transistor having an end connected to the source line and another end connected to the variable resistance element; and
applying the second voltage to a gate of the second selective transistor having an end connected to the source line and another end connected to the variable resistance element.
